(19) United States
(12) Patent Application Publication
(10) Pub. No.: US 2013/0021725 A1
(43) Pub. Date: Jan. 24, 2013

(54) COVER MECHANISM AND ELECTRONIC DEVICE USING SAME

(71) Applicant: GUO-ZHAO HUANG, Shenzhen City (CN)

(72) Inventor: GUO-ZHAO HUANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/455,811

(22) Filed: Apr. 25, 2012

(30) Foreign Application Priority Data
Jul. 20, 2011 (CN) 201110203621.6

(51) Int. Cl. H05K 5/03; B65D 45/16; B65D 45/00

(52) U.S. Cl. 361/679.01; 220/315; 220/324

(57) ABSTRACT

An electronic device includes a housing, an external interface assembly, and a cover mechanism. The cover mechanism is used for either covering and protecting connectors of the external interface assembly, or exposing out the external interface assembly. Accordingly, the cover mechanism has at least three positions, and can move between a locked position, a partially released position, and a completely released position.

### BACKGROUND

1. Technical Field

The present disclosure relates to cover mechanisms used in electronic devices.

2. Description of the Related Art

Electronic devices usually have external interfaces (e.g., universal serial bus (USB)) for electrically connecting peripheral devices (e.g., printers), accessories (e.g., USB flash drives) or other electronic devices. Such external interfaces should be protected by cover mechanisms from e.g., dust or water, to maintain proper functioning.

The cover mechanisms usually include covers with locks. The covers are typically locked to the electronic devices by latches to cover the area through which the interfaces of electronic devices are exposed. However, the covers are often not permanently attached to the electronic device. Thus, the covers may easily be misplaced or lost when not locked to the electronic devices.

Therefore, there is room for improvement within the art.

### BRIEF DESCRIPTION OF THE DRAWINGS

Many aspects of the present cover mechanism and electronic device using same can be better understood with reference to the following drawings. The components in the drawings are not necessarily drawn to scale, the emphasis instead being placed upon clearly illustrating the principles of the present cover mechanism and electronic device. Moreover, in the drawings, like reference numerals designate corresponding parts throughout the several views.

FIG. 1 is an exploded and isometric view of an exemplary electronic device including an exemplary cover mechanism.

FIG. 2 is an isometric view of the cover mechanism shown in FIG. 1 in a locked position.

FIG. 3 is similar to FIG. 2 at a different view angle.

FIG. 4 is similar to FIG. 3, but in a partially released position.

FIG. 5 is similar to FIGS. 3 and 4, but in a completely released position.

### DETAILED DESCRIPTION

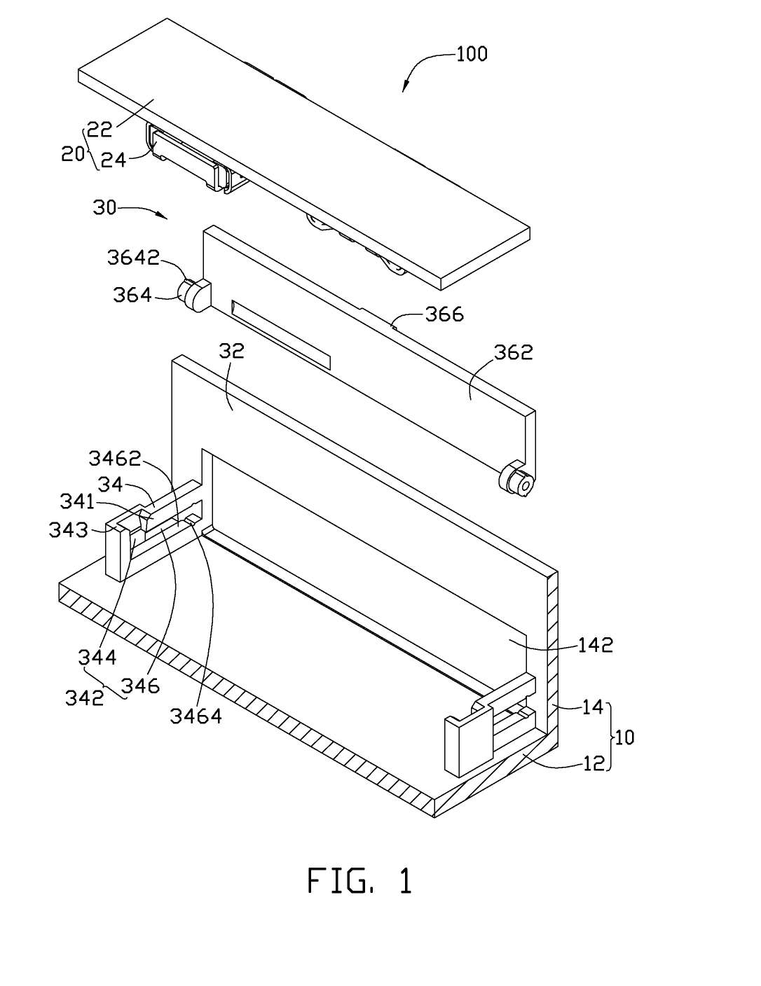

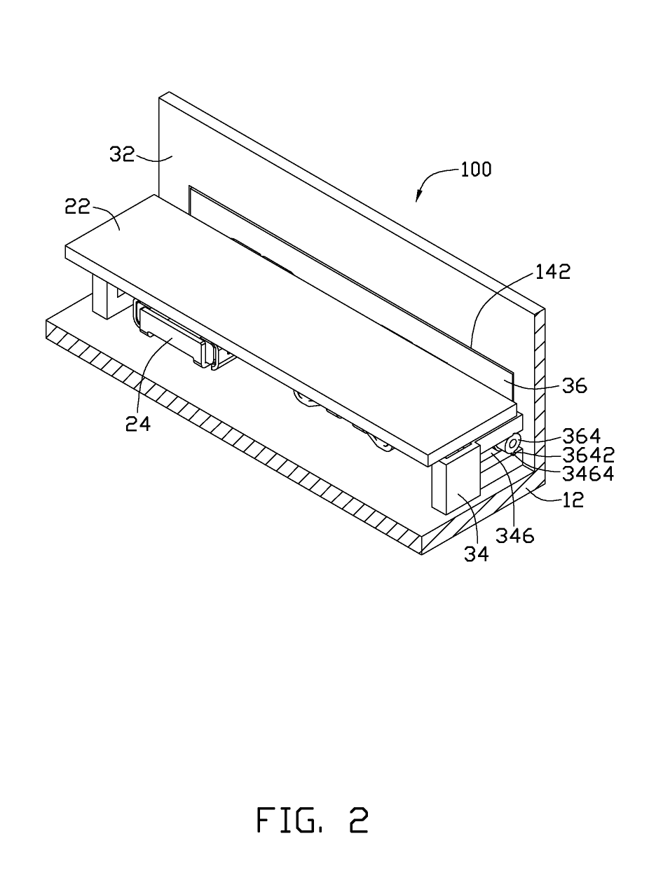

FIGS. 1 through 5 show an exemplary cover mechanism 100 included in an exemplary electronic device such as a mobile phone. For illustrated purpose, only part of the electronic device are shown including a housing 10, an external interface assembly 20, and a cover member 30. The cover mechanism 100 includes a base member 32, which may be a portion of the housing 10, and includes a first wall 12 and a second wall 14. The cover mechanism 100 is used for either covering and protecting connectors 24 of the external interface assembly 20, or exposing out the connectors 24. The connectors 24 are electrically disposed on a circuit board 22 and positioned in aligning with an interface hole 142 defined in the base member 32.

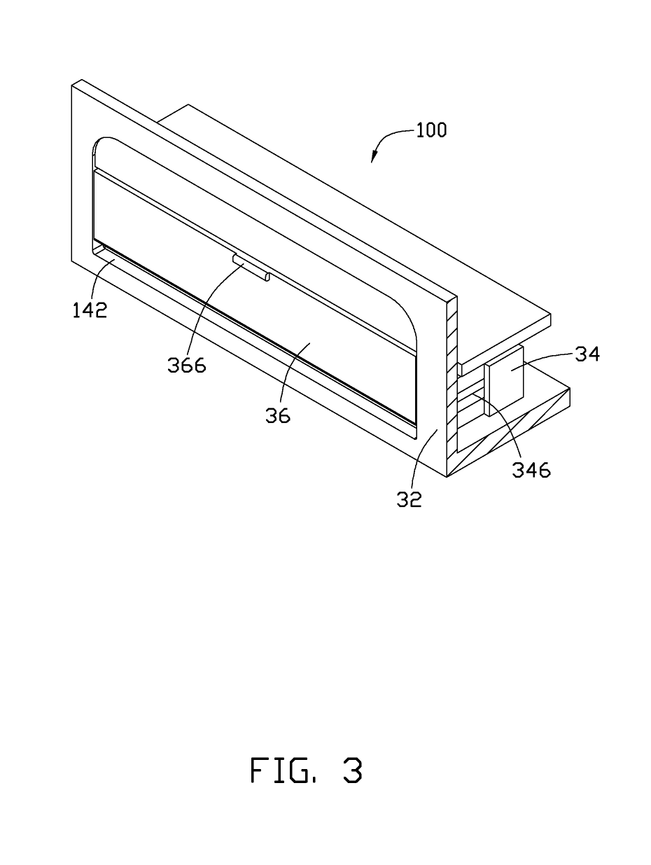

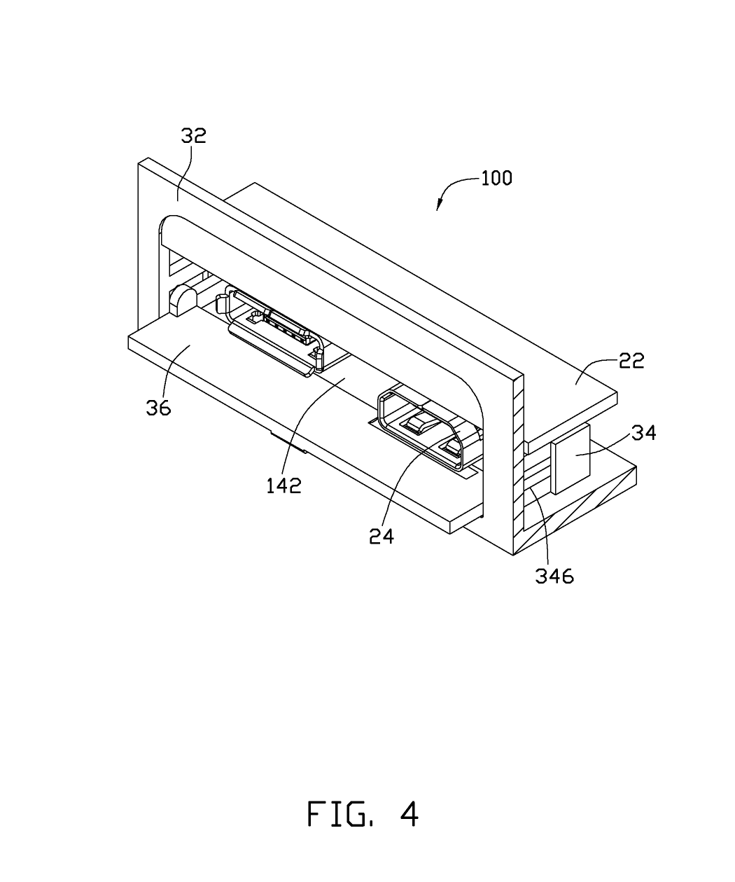

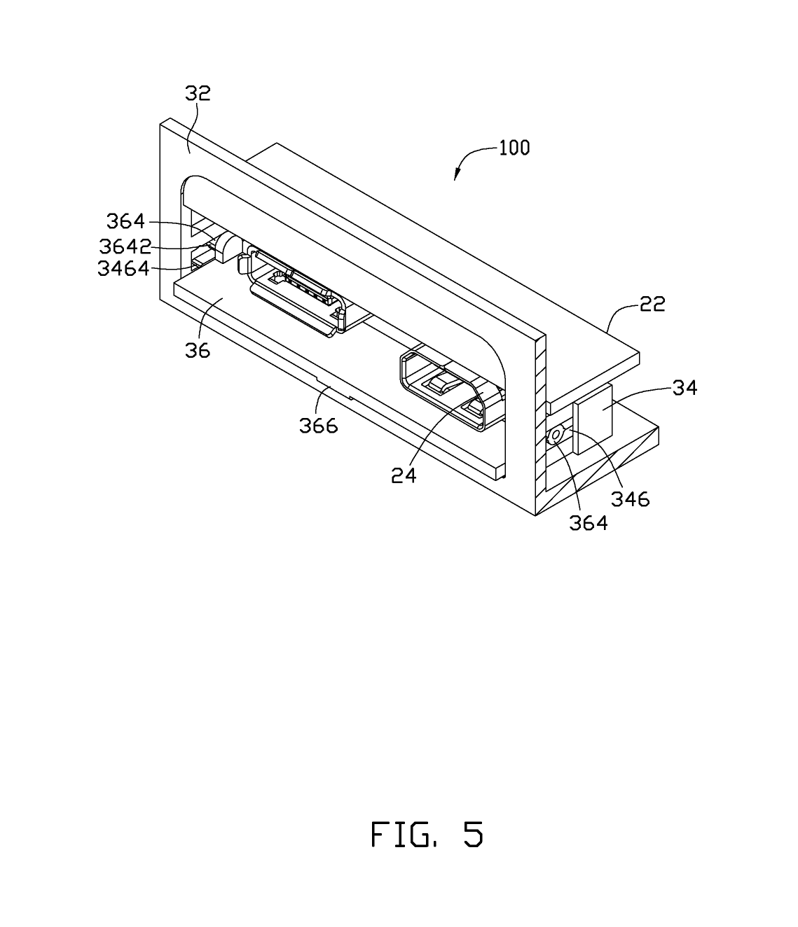

For achieving above purposes, the cover mechanism 100 has at least three positions as shown in FIGS. 3 through 5. The cover member 30 can move between a locked position (FIG. 3), a partially released position (FIG. 4), and a completely released position (FIG. 5). In the locked position, the cover member 30 is locked to the base member 32 to cover the interface hole 142. In the partially released position, the cover member 30 exposes the interface hole 142 while being physically attached to the base member 32. In the completely released position, the cover member 30 can move inwardly into the base member 32, and thus not to interfere with operations to the external interface assembly 20 (see FIG. 5).

Referring in detail to FIG. 1, the cover mechanism 100 includes the cover member 30 and a base member 32. The cover member 30 includes two protruding shafts 364 at the opposite sides. The interface hole 142 is defined through the second wall 14. The base member 32 has two arms 34 protruding from the second wall 14 and above the first wall 12. The two arms 34 are oppositely located at two sides of the interface hole 142, and define two opposite shaft grooves 346. Thus, the two shafts 364 can mount in, slide, and rotate within the shaft grooves 346. The sliding of the shafts 364 in the shaft grooves 346 enables the cover member 30 to move between the partially released position (FIG. 4) and the completely released position (FIG. 5). The rotation of the shafts 364 in the shaft grooves 346 enables the cover member 30 to move between the partially released position (FIG. 4) and the locked position (FIG. 3).

For locking the cover mechanism 100 in the locked position, each shaft 364 defines two opposite locking bars 3642, and each arm 34 defines two opposite locking slits 3464. The locking bars 3642 protrude from a circumferential surface of the shaft 364. The locking slits 3464 define in interior wall 3462 of the shaft groove 346, adjacent to the interface hole 142. The locking bars 3642 can lock in the locking slits 3464, maintaining the locking of the cover mechanism 100.

For mounting the cover member 30 to the base member 32, each arm 34 defines an insertion groove 344 from an upper wall 341 vertically communicating with the shaft groove 346. The insertion groove 344 allows the shaft 364 mounting through and into the shaft groove 346. Accordingly, the cover member 30 is slidably and rotatably mounted with the base member 32.

For a convenient releasing locking of the cover mechanism 100, a protrusion 366 is formed on an exterior surface of the cover member 30. The protrusion 366 can be easily grasped with a pulling force to rotate the cover member 30 relative to the base member 32.

Referring further to FIGS. 3 through 5, when the external interfaces assembly 20 needs to electrically connect peripheral devices, the cover mechanism 100 in the locked position needs to be released to the partially released position. During the process, the cover member 30 rotates relative to the base member 32 and the shaft 364 rotate relative to the shaft groove 346, overcoming the locking of the locking bars 3642 by the locking slits 3464. When released, the locking bars 3642 release out of the locking slits 3464. The main body 36 of the cover member 30 rotates to be planar with the shaft groove 346. The connectors 24 are exposed out from the cover member 30 and can connect peripheral devices.

For a convenient operation of the connectors 24 without interference with the main body 36, the cover mechanism 100 needs a further transmission from the partially released position to the completely released position. During the process, the main body 36 is pushed inwardly into the base member 32. The shafts 34 slide along the shaft grooves 346, until the end of the main body 36 abuts against the end wall of the arm 34 and the main body 36 is completely received in the base member 32.

It is to be understood that even though numerous characteristics and advantages of the present embodiments have been set forth in the foregoing description, together with details of assemblies and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A cover mechanism for covering an interface hole of an electronic device, the cover mechanism comprising:
a base member;
a cover member configured for movement between:
a locked position, where the cover member is locked to the base member to cover the interface hole;
a partially released position, where the cover member exposes the interface hole while being physically attached to the base member; and
a completely released position, where the cover member can move inwardly into the base member.

2. The cover mechanism as claimed in claim 1, wherein the cover member comprises two shafts, the base member comprises two arms defining two shaft grooves, the two shafts sliding and rotating within the shaft grooves.

3. The cover mechanism as claimed in claim 2, wherein the sliding of the shafts in the shaft grooves enables the cover member to move between the partially released position and the completely released position.

4. The cover mechanism as claimed in claim 2, wherein the rotation of the shafts in the shaft grooves enables the cover member to move between the partially released position and the locked position.

5. The cover mechanism as claimed in claim 2, wherein the base member comprises a first wall and a second wall connecting the first wall, the two arms protrude from the second wall and above the first wall, the two arms are oppositely located at two sides of the interface hole.

6. The cover mechanism as claimed in claim 2, wherein each shaft defines two locking bars, and each arm defines two locking slits, the locking bars are capable of locking in the locking slits, maintaining the locking position of the cover mechanism.

7. The cover mechanism as claimed in claim 6, wherein the locking bars protrude around the shaft, and the locking slits are defined in an interior wall of the shaft groove.

8. The cover mechanism as claimed in claim 6, wherein the locking of the locking bars release out of the locking slits by rotating the cover member relative to the base member, and the cover member rotates to be planar with the shaft groove.

9. The cover mechanism as claimed in claim 2, wherein each arm defines an insertion groove vertically communicating with the shaft groove, the shaft is mounted through the insertion groove and into the shaft groove.

10. An electronic device, comprising:
a housing defining an interface hole;
a cover mechanism for covering or exposing the interface hole, comprising:
a base member being a portion of the housing;
a cover member configured for movement between:
a locked position, where the cover member is locked to the base member to cover the interface hole;
a partially released position, where the cover member exposes the interface hole while being physically attached to the base member; and
a completely released position, where the cover member can move inwardly into the base member.

11. The electronic device as claimed in claim 10, wherein the cover member comprises two shafts, the base member comprises two arms defining two shaft grooves, the two shafts sliding and rotating within the shaft grooves.

12. The electronic device as claimed in claim 11, wherein the sliding of the shafts in the shaft grooves enables the cover member to move between the partially released position and the completely released position.

13. The electronic device as claimed in claim 11, wherein the rotation of the shafts in the shaft grooves enables the cover member to move between the partially released position and the locked position.

14. The electronic device as claimed in claim 11, wherein the base member comprises a first wall and a second wall connecting the first wall, the two arms protrude from the second wall and above the first wall, the two arms are oppositely located at two sides of the interface hole.

15. The electronic device as claimed in claim 11, wherein each shaft defines two locking bars, and each arm defines two locking slits, the locking bars are capable of locking in the locking slits, maintaining the locking position of the cover mechanism.

16. The electronic device as claimed in claim 15, wherein the locking bars protrude around the shaft, and the locking slits are defined in an interior wall of the shaft groove.

17. The electronic device as claimed in claim 15, wherein the locking of the locking bars release out of the locking slits by rotating the cover member relative to the base member, and the cover member rotates to be planar with the shaft groove.

18. The electronic device as claimed in claim 11, wherein each arm defines an insertion groove vertically communicating with the shaft groove, the shaft is mounted through the insertion groove and into the shaft groove.

19. The electronic device as claimed in claim 10, further comprising an external interface assembly having a connector and circuit board electrically connecting the connector, the connector is positioned in aligning with the interface hole.
